(19) United States
(12) Patent Application Publication
(10) Pub. No.: US 2025/0125289 A1
(43) Pub. Date: Apr. 17, 2025

(54) INTEGRATED PACKAGE AND METHOD FOR MAKING THE SAME

(71) Applicant: STATS ChipPAC Pte. Ltd., Singapore (SG)

(72) Inventors: KaiChong CHAN, Singapore (SG); PeiEe Linda CHUA, Singapore (SG); Yaojian LIN, Wuxi (CN)

(21) Appl. No.: 18/827,895

(22) Filed: Sep. 9, 2024

(30) Foreign Application Priority Data
Oct. 11, 2023 (CN) 202311315506.7

(51) Int. Cl. H01L 23/66; H01L 21/48; H01L 21/56; H01L 23/00; H01L 23/31; H01L 23/498

(52) U.S. Cl. CPC H01L 23/66; H01L 21/4857; H01L 21/56; H01L 23/3135; H01L 24/16; H01L 23/49833; H01L 24/32; H01L 24/73; H01L 2223/6677; H01L 2224/16225; H01L 2224/32225; H01L 2224/73253; H01L 2924/1815

(57) ABSTRACT

An integrated package and a method for making the same are provided. The integrated package includes: an antenna module including: an antenna module substrate; and a top antenna structure disposed on the antenna module substrate; a first encapsulant encapsulating the antenna module; a first redistribution structure disposed on a bottom surface of the first encapsulant, wherein the first redistribution structure includes a bottom antenna structure configured for coupling electromagnetic energy with the top antenna structure; and a semiconductor chip mounted on a bottom surface of the first redistribution structure and electrically coupled with the bottom antenna structure.

### TECHNICAL FIELD

The present application generally relates to semiconductor technology, and more particularly, to an integrated package and a method for making the same.

### BACKGROUND OF THE INVENTION

The semiconductor industry is constantly faced with complex integration challenges as consumers want their electronics to be smaller, faster and higher performance with more and more functionalities packed into a single device. Antenna-in-Package (AiP) has emerged as the mainstream antenna packaging technology for various applications. The AiP allows integration of an antenna and a RF chip (e.g., transceiver) in a single package. However, the conventional AiP technology is complex, resulting in excess cost and low reliability. Therefore, a need exists for a simple and cost effective AiP technology.

### SUMMARY OF THE INVENTION

An objective of the present application is to provide a simple and cost effective integrated package.

According to an aspect of the present application, an integrated package is provided. The integrated package may include: at least one antenna module including: an antenna module substrate and a top antenna structure disposed on the antenna module substrate; a first encapsulant encapsulating the antenna module; a first redistribution structure disposed on a bottom surface of the first encapsulant, wherein the first redistribution structure includes a bottom antenna structure configured for coupling electromagnetic energy with the top antenna structure; and a semiconductor chip mounted on a bottom surface of the first redistribution structure and electrically coupled with the bottom antenna structure.

According to another aspect of the present application, a method for making an integrated package is provided. The method may include: providing at least one antenna module, wherein the antenna module includes an antenna module substrate and a top antenna structure disposed on the antenna module substrate; attaching the antenna module on a carrier; forming a first encapsulant on the carrier to encapsulate the antenna module; removing the carrier to expose a bottom surface of the encapsulant; forming a first redistribution structure on the bottom surface of the first encapsulant, wherein the first redistribution structure includes a bottom antenna structure configured for coupling electromagnetic energy with the top antenna structure; and mounting a semiconductor chip on the first redistribution structure, wherein the semiconductor chip is electrically coupled with the bottom antenna structure.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view of an integrated package according to an embodiment of the present application.

FIG. 2 is a cross-sectional view of an integrated package according to another embodiment of the present application.

FIG. 3 is a cross-sectional view of an integrated package according to another embodiment of the present application.

FIGS. 4A to 4E are cross-sectional views illustrating various steps of a method for making an antenna module according to an embodiment of the present application.

FIGS. 5A to 5J are cross-sectional views illustrating various steps of a method for making an integrated package according to an embodiment of the present application.

FIGS. 6A to 6H are cross-sectional views illustrating various steps of a method for making an integrated package according to another embodiment of the present application.

FIGS. 7A to 7F are cross-sectional views illustrating various steps of a method for making an integrated package according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

In conventional AiP devices, electrical signals may travel from an integrated circuit chip to an antenna through one or more traces and/or one or more conductive vias embedded within dielectric materials. However, the dielectric materials, such as a molding compound, may suffer from current leakage, stray capacitance, etc. Accordingly, the performance of conventional AiP devices may be impeded.

In some embodiments of the present application, an integrated package is provided. The integrated package includes an antenna module embedded in an encapsulant, and the antenna module includes a top antenna structure. A redistribution structure including a bottom antenna structure is formed on a bottom surface of the encapsulant, and a semiconductor chip is mounted on the redistribution structure and electrically coupled with the bottom antenna structure. The bottom antenna structure is configured for coupling electromagnetic energy with the top antenna structure, and thus the semiconductor chip can transmit and receive electromagnetic signals through the electromagnetically coupled bottom and top antenna structures. The integrated package of the present application has a simpler structure and is more cost effective. Further, as there are no wire connections between the bottom antenna structure and the top antenna structure and no conductive vias formed in the encapsulant, the encapsulant may not suffer from current leakage. In addition, the antenna module and the semiconductor chip are disposed on two opposite sides of the redistribution structure to reduce interferences therebetween.

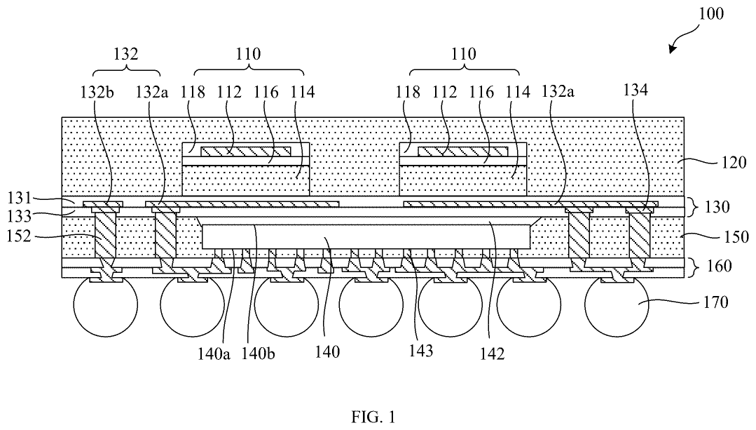

FIG. 1 illustrates a cross-sectional view of an integrated package 100 according to an embodiment of the present application. The integrated package 100 includes two antenna modules 110 each having a top antenna structure 112, a first redistribution structure (RDS) 130 including two bottom antenna structures 132a, and a semiconductor chip 140 electrically coupled with the bottom antenna structures 132a. Each bottom antenna structure 132a is configured for coupling electromagnetic energy with a respective top antenna structure 112, such that the semiconductor chip 140 can transmit and receive electromagnetic signals through the electromagnetically coupled bottom and top antenna structures 132a, 112.

Referring to FIG. 1, the integrated package 100 includes a first encapsulant 120. The two antenna modules 110 are embedded in the first encapsulant 120. The first encapsulant 120 may be made of a molding compound such as a polymer composite material. For example, the molding compound may include epoxy resin, epoxy resin with filler, epoxy acrylate with filler, or polymer with proper filler, but the scope of this application is not limited thereto. The first encapsulant 120 is nonconductive, provides structural support, and environmentally protects the antenna modules 110 from external elements and contaminants. In some embodiments, the first encapsulant 120 may be formed using compressive molding, transfer molding, liquid encapsulant molding, or other suitable molding processes. The antenna modules 110 may be encapsulated by the first encapsulant 120 during the molding process.

As shown in FIG. 1, the two antenna modules 110 are embedded in the first encapsulant 120. Each antenna module 110 may be pre-formed, and at least include an antenna module substrate 114 and the top antenna structure 112. In the example shown in FIG. 1, a bottom surface of the antenna module substrate 114 is substantially flush or coplanar with a bottom surface of the first encapsulant 120. In some embodiments, the antenna module substrate 114 may include a molding compound, for example, encapsulant, and can be formed using a molding process. For example, the antenna module substrate 114 may have a same or different material as the first encapsulant 120. In some embodiments, the antenna module substrate 114 may include a PCB prepreg component and a PCB core component that are assembled together. The PCB core component may include glass-reinforced epoxy laminate sheets. The PCB prepreg component may be of a dielectric material and can be packed in between two PCB core components to provide desired insulation performance. Further, the top antenna structure 112 is disposed above the antenna module substrate 114 and is configured for coupling electromagnetic energy with the bottom antenna structure 132a through mutual coupling effects. The top antenna structure 112 may have a similar shape as the bottom antenna structure 132a in some embodiments. For example, when viewed from top of the integrated package 100, the top antenna structure 112 may at least partially overlap with the bottom antenna structure 132a. The more the top antenna structure 112 and the bottom antenna structure 132a overlap, the better the mutual coupling effects are.

In the example shown in FIG. 1, the antenna module 110 further includes a bottom passivation layer 116 and a cap passivation layer 118. The bottom passivation layer 116 is disposed between the antenna module substrate 114 and the top antenna structure 112 for providing electrical isolation and improving adhesion. The cap passivation layer 118 is disposed on the bottom passivation layer 116 and covers the top antenna structure 112. The cap passivation layer 118 can environmentally protect the top antenna structure 112 from external elements and contaminants. In some embodiments, the bottom passivation layer 116 and/or the cap passivation layer 118 may be made of dielectric materials having low loss tangent properties or dissipation factors (Df, for example, ≤0.02). In some embodiments, the dielectric materials may have low dielectric constants (Dk, for example, ≤4) or high Dk (for example, >4) according to actual needs. It should be noted that, the bottom passivation layer 116 and the cap passivation layer 118 may be optional. In some other embodiments, the antenna module may include only one of the bottom passivation layer and the cap passivation layer, or may include neither the bottom passivation layer nor the cap passivation layer.

In the example shown in FIG. 1, the first encapsulant 120 covers the top surface and lateral surfaces of the antenna modules 110 to protect the antenna modules 110. For example, the top surface of the first encapsulant 120 is 20 μm higher than the top surface of the antenna modules 110. However, the scope of the present application is not limited thereto. For example, one or more surfaces such as the lateral surface of the antenna module 110 may be exposed from the first encapsulant 120.

Referring to FIG. 1, the first redistribution structure 130 is formed on a bottom surface of the first encapsulant 120. The first redistribution structure 130 may include one or more dielectric layers and one or more conductive layers between and through the dielectric layers. The conductive layers may define pads, traces and plugs through which electrical signals or voltages can be distributed horizontally and vertically across the first redistribution structure 130.

In the example shown in FIG. 1, a first dielectric layer 131 of the first redistribution structure 130 is disposed on the bottom surface of the first encapsulant 120, and a first redistribution layer (RDL) 132 is formed in the first dielectric layer 131. Further, a second dielectric layer 133 is formed on a bottom surface of the first dielectric layer 131, and a second redistribution layer 134 is formed in the second dielectric layer 133 and electrically connected to the first redistribution layer 132. In some embodiments, the first dielectric layer 131 and the second dielectric layer 133 may include silicon nitride, silicon oxynitride, FTEOS, SiCOH, polyimide, benzocyclobutene (BCB) or other organic polymers, or combinations thereof. The first redistribution layer 132 and the second redistribution layer 134 may include one or more of Cu, Al, Sn, Ni, Au, Pd, Ag, Ti, TiW or any other suitable electrically conductive materials. In some embodiments, the first redistribution structure 130 shown in FIG. 1 can be formed in accordance with a standard Embedded Wafer Level Ball Grid Array (eWLB) process, but aspects of the present application are not limited thereto. It could also be understood that the first redistribution structure 130 may be implemented in various structures and types, and the example shown in FIG. 1 is used only for illustration. For example, the number of redistribution layers is not limited to two as shown in FIG. 1.

Continuing referring to FIG. 1, the first redistribution layer 132 may include a first portion (i.e., the bottom antenna structure 132a). The bottom antenna structure 132a may include various types or shapes of antennas such as planar antennas, so as to transmit and/or receive wireless communication signals from or to the semiconductor chip 140. For example, the bottom antenna structure 132a may take the form of a planar coil that meanders in the first dielectric layer 131. The bottom antenna structure 132a can be electrically connected to the semiconductor chip 140 via the second redistribution layer 134, at least one conductive pillar 152 and a second redistribution structure 160 as shown in FIG. 1. In the example shown in FIG. 1, the first redistribution layer 132 further includes a second portion 132b serving as an interconnect structure.

Referring to FIG. 1, the semiconductor chip 140 is mounted on the bottom surface of the first redistribution structure 130 via an adhesive layer 142. The adhesive layer 142 may include, for example, a layer of adhesive paste, a layer of liquid adhesive, a preformed double-sided adhesive tape or sheet (e.g., a die-attach tape), a printed adhesive, etc. The semiconductor chip 140 may include one or more digital chips, analog chips or mixed signal chips, such as application-specific integrated circuit (“ASIC”) chips, sensor chips, wireless and radio frequency (RF) chips, memory chips, logic chips or voltage regulator chips. In some embodiments, the semiconductor chip 140 may include an integrated circuit chip for wireless communication and/or signal processing, which may require antennas for transmitting and receiving wireless signals. In some embodiments, the semiconductor chip 140 may further include output and/or input circuits for an antenna structure for wireless communication.

As shown in FIG. 1, the semiconductor chip 140 may be smaller a semiconductor package, and may be manufactured using a surface fabrication process or other similar processes, having an active surface 140a and a non-active surface 140b which is opposite to the active surface 140a. Various types of analog or digital circuits, which may be implemented as active devices and/or passive devices, may be formed close to the active surface 140a, and electrically coupled to certain interconnection pads/bumps 143 exposed from the active surface 140a via metal interconnect structures of the semiconductor chip 140. In contrast, the non-active surface 140b of the semiconductor chip 140 may not have any conductive patterns exposed therefrom, but the scope of this application is not limited thereto. In the example shown in FIG. 1, the non-active surface 140b of the semiconductor chip 140 is bonded to first redistribution structure 130 via the adhesive layer 142, and the interconnection bumps 143 on the active surface 140a are electrically connected to the second redistribution structure 160.

Referring to FIG. 1, a plurality of conductive pillars 152 are formed on the first redistribution structure 130 to couple the first redistribution structure 130 to the second redistribution structure 160. For example, each conductive pillar 152 may be formed on a respective portion of the second redistribution layer 134 of the first redistribution structure 130, and extends vertically through a second encapsulant 150 which is disposed on the bottom surface of the first redistribution structure 130 and encapsulating the semiconductor chip 140. The conductive pillars 152 may include any of a variety of conductive materials (e.g., Cu, Al, Ag, Au, Ni, alloys thereof, etc.). For example, the conductive pillars 152 may include copper (e.g., pure copper, copper with some impurities, etc.), a copper alloy, etc.

As shown in FIG. 1, the second encapsulant 150 may cover lateral surfaces of the conductive pillars 152 and the interconnection bumps 143, but leave bottom surfaces of them exposed, such that the conductive pillars 152 and the interconnection bumps 143 can be electrically connected with the second redistribution structure 160 through these exposed surfaces. The second encapsulant 150 may be made of the same material as the first encapsulant 120, but the scope of this application is not limited thereto. In the example shown in FIG. 1, the second redistribution structure 160 includes two dielectric layers and two conductive layers formed in the two dielectric layers. However, it could be understood that the configuration of the second redistribution structure 160 (and the first redistribution structure 130) shown in the figure is merely exemplary and not limiting, and may vary according to actual needs.

Moreover, a plurality of conductive bumps 170 are formed on the bottom surface of the second redistribution structure 160. In some embodiments, a plurality of contact pads or under bump metallization (UBM) structures are formed on the bottom surface of the second redistribution structure 160 and electrically coupled with the redistribution layers in the second redistribution structure 160, and the conductive bumps 170 are formed on the contact pads or under bump metallization structures, respectively. In the example shown in FIG. 1, the conductive bumps 170 are illustrated as solder bumps, but the scope of the present application is not limited thereto. In some other embodiments, the conductive bumps 170 may include other conductive bumps such as microbumps, metal pillars, or copper balls. In a case where the integrated package 100 is mounted on an external device or substrate, such as a printed circuit board (PCB), the conductive bumps 170 may be used for electrically connecting the integrated package 100 to the external device or substrate.

It should be noted that each of the two antenna modules 110 in FIG. 1 includes a top antenna structure 112, which is coupled to a respective bottom antenna structure 132a connected to the semiconductor chip 140. Accordingly, the two top antenna structures 112 may jointly or individually transmit electromagnetic radiation to and/or receive electromagnetic radiation from the two bottom antenna structures 132a connected to the semiconductor chip 140. However, the number or configuration of the antenna structures is not limited to the example shown in FIG. 1. For example, the integrated package may include only one or more than two top antenna structures in other embodiments, or more layers of antenna structures may be formed within the integrated package. In the example shown in FIG. 1, the two top antenna structures 112 are coplanar with each other, but aspects of the present application are not limited thereto. In some other embodiments, the two top antenna structures may be at different levels, such that the two antenna modules can have different heights for different target frequencies.

Further, as the top antenna structures 112 and the bottom antenna structure 132a are electromagnetically coupled with each other, it is desired that a distance between the top antenna structures 112 and the bottom antenna structures 132a be carefully controlled in consideration of patterns of the top antenna structures 112 and the bottom antenna structures 132a, and the characteristics (including the dissipation factor (Df) and the dielectric constant (Dk)) of the antenna module substrate 114, the first dielectric layer 131, and any other intermediate layers. For example, the distance between the top antenna structures 112 and the bottom antenna structure 132a may be 150 μm, 200 μm, 250 μm, 270 μm, 280 μm, 290 μm, 310 μm, 360 μm, or other values according to the specific application scenario. However, it can be appreciated that the distance between the top antenna structures 112 and the bottom antenna structure 132a can be modified or adjusted based on actual calculation or simulation results, for example, using commercial electromagnetic simulation software such ANSYS HFSS.

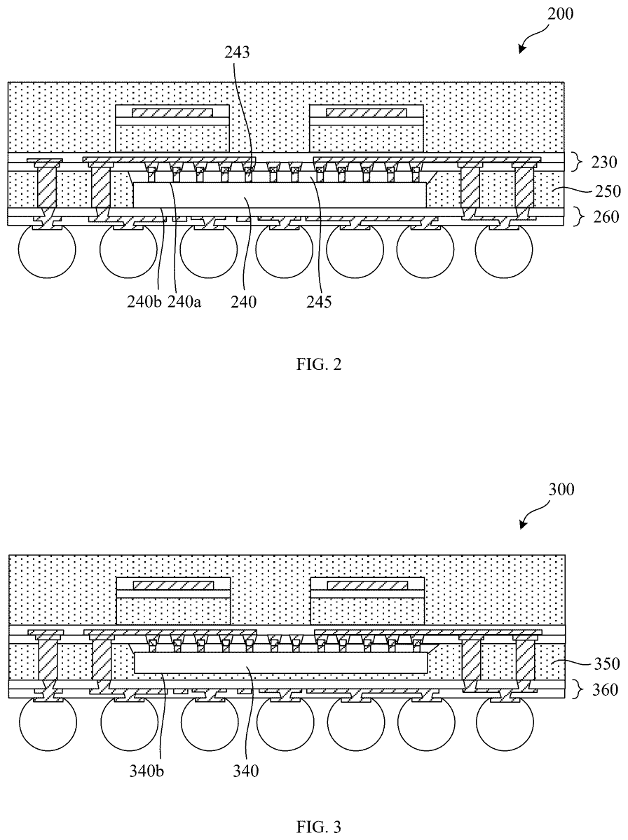

Referring to FIG. 2, an integrated package 200 is illustrated according to another embodiment of the present application. The integrated package 200 may have similar structures and configurations as the integrated package 100 shown in FIG. 1. The similar or same parts between the integrated package 200 and the integrated package 100 will not be repeated herein.

The integrated package 200 of FIG. 2 is different from the integrated package 100 of FIG. 1 in that a semiconductor chip 240 of FIG. 2 is mounted on a bottom surface of a first redistribution structure 230 by a flip-chip bonding technique. Specifically, as shown in FIG. 2, the semiconductor chip 240 has an active surface 240a and a non-active surface 240b which is opposite to the active surface 240a. A plurality of interconnection pads/bumps 243 may be formed on the active surface 240a of the semiconductor chip 240, and then the semiconductor chip 240 is mounted on the bottom surface of a first redistribution structure 230 via the interconnection pads/bumps 243. The interconnection pads/bumps 243 electrically connect circuits or devices formed in the semiconductor chip 240 to the conductive patterns in the first redistribution structure 230. In the example shown in FIG. 2, the non-active surface 240b of the semiconductor chip 240 is exposed from a bottom surface of a second encapsulant 250 and contacts with a second redistribution structure 260.

Optionally, an underfill encapsulant 245 may be formed between the bottom surface of the first redistribution structure 230 and the active surface 240a of the semiconductor chip 240. The underfill encapsulant 245 may fill in any gaps between the first redistribution structure 230 and the semiconductor chip 240 and optionally cover lateral surfaces of the semiconductor chip 240. The underfill encapsulant 245 may include a polymer composite material, such as epoxy resin, epoxy acrylate, or polymer with or without a filler. The underfill encapsulant 245 may provide mechanical support to the interconnection between the first redistribution structure 230 and the semiconductor chip 240, helping to mitigate the risk of crack or delamination due to differential thermal expansion between the first redistribution structure 230 and the semiconductor chip 240.

Referring to FIG. 3, an integrated package 300 is illustrated according to another embodiment of the present application. The integrated package 300 may have similar structures and configurations as the integrated package 200 shown in FIG. 2. The similar or same parts between the integrated package 300 and the integrated package 200 will not be repeated herein.

The integrated package 300 of FIG. 3 is different from the integrated package 200 of FIG. 2 in that a non-active surface 340b of a semiconductor chip 340 is above a bottom surface of a second encapsulant 350. That is, the non-active surface 340b of the semiconductor chip 340 is covered by the second encapsulant 350, and at least a portion of the second encapsulant 350 is disposed between the semiconductor chip 350 and a second redistribution structure 360.

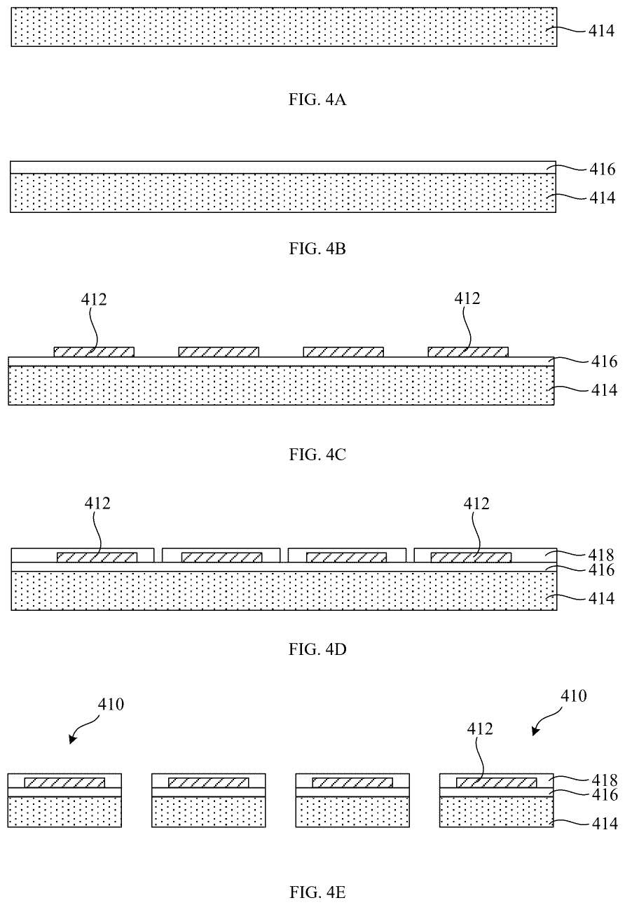

Referring to FIGS. 4A to 4E, various steps of a method for forming an antenna module are illustrated according to an embodiment of the present application. For example, the method may be used to form the antenna module 110 shown in FIG. 1. In the following, the method will be described with reference to FIGS. 4A to 4E in more details.

As shown in FIG. 4A, a blanket molded substrate 414 is provided. The molded substrate 414 may include a molding compound such as a polymer composite material. For example, the molding compound may include epoxy resin, epoxy resin with filler, epoxy acrylate with filler, or polymer with proper filler. The molded substrate 414 may be formed using compressive molding, transfer molding, liquid encapsulant molding, or other suitable molding processes. The molded substrate 414 can provide structural support for an antenna structure formed in subsequent steps.

As shown in FIG. 4B, a bottom passivation layer 416 is formed on the molded substrate 414. The bottom passivation layer 416 may include silicon nitride, silicon oxynitride, fluorinated tetraethylorthosilicate (FTEOS), SiCOH, polyimide, benzocyclobutene (BCB) or other organic polymers, or combinations thereof, and may be formed by spray coating, sputtering, or any other suitable deposition process.

As shown in FIG. 4C, one or more top antenna structures 412 can be formed on the bottom passivation layer 416. In some embodiments, a metal layer (for example, Cu, Al, Sn, Ni, Au, Pd, Ag, Ti, TiW or any other suitable electrically conductive materials) may be formed on the bottom passivation layer 416 by spray coating, plating, sputtering, or any other suitable metal deposition process, and then is patterned to a desired shape by a photolithography process to form the antenna structures 412. However, the scope of the present application is not limited thereto, and other suitable processes can be used to form the top antenna structures 412. For example, one or more additional passivation layers and corresponding antenna structures may be formed above the top antenna structures 412.

As shown in FIG. 4D, a cap passivation layer 418 is formed on the top antenna structures 412. The passivation layer 418 covers a top surface and lateral surfaces of the top antenna structures 412, and can environmentally protect the top antenna structure 412 from external elements and contaminants. The cap passivation layer 418 may have a same or different material as the bottom passivation layer 416.

As shown in FIG. 4E, the blanket molded substrate 414 is singulated to form a plurality of individual antenna modules 410. In some embodiments, the molded substrate 414 can be singulated into the antenna modules 410 using a saw blade. In some other examples, a laser cutting tool can also be used to singulate the molded substrate 414.

In some embodiments, before the molded substrate 414 is singulated, the molded substrate 414 may be flipped and the cap passivation layer 418 may be attached to a carrier. Then, a back-grinding process may be performed to reduce a thickness of the molded substrate 414. After grinding, the molded substrate 414 can be removed from the carrier.

It could be understood that the method described with reference to FIGS. 4A to 4E can also be used to form the antenna modules with other configurations (for example, with the bottom passivation layer and/or the cap passivation layer omitted) by varying specific processes or materials, which will not be elaborated herein.

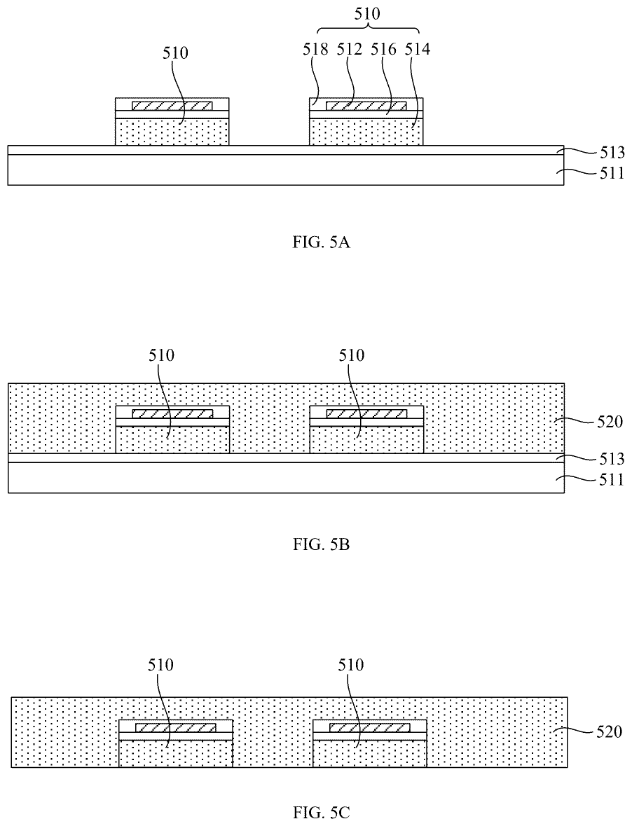

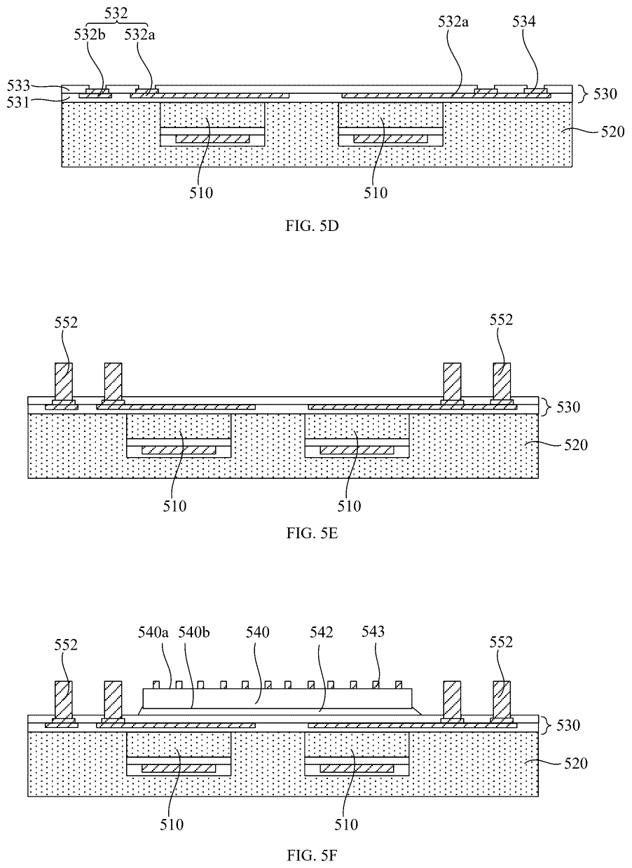

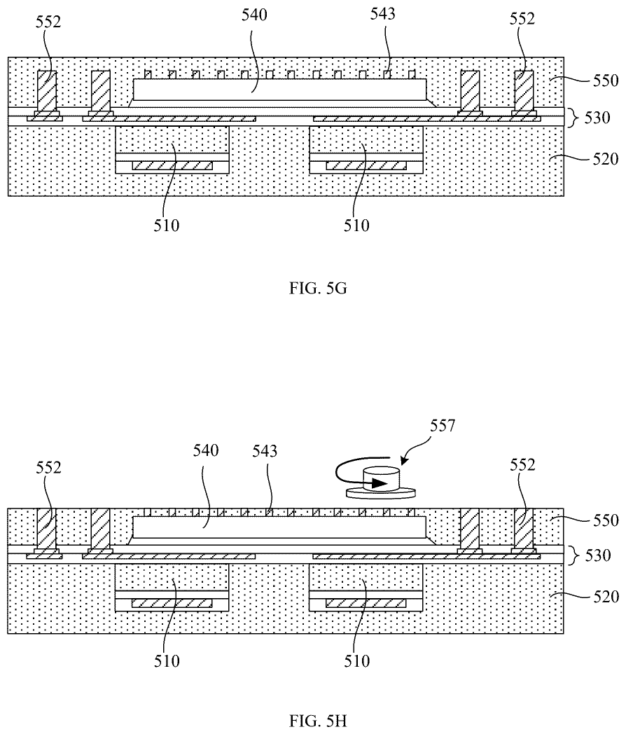

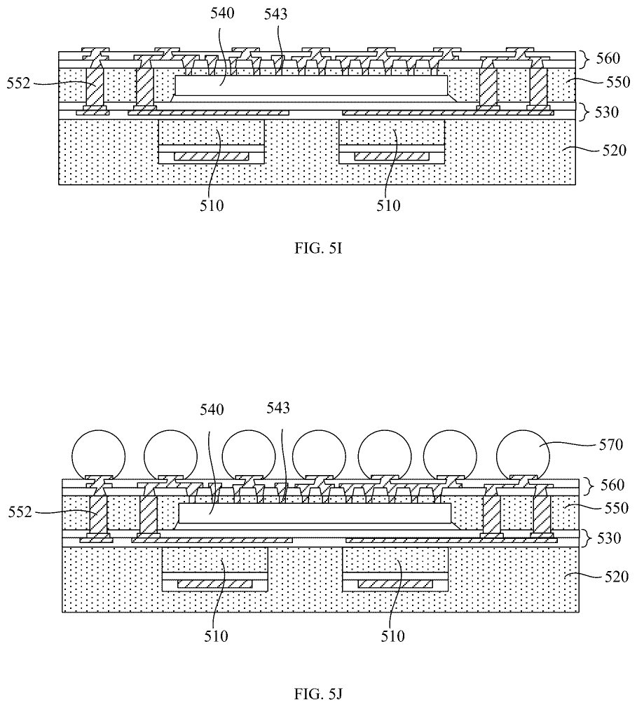

Referring to FIGS. 5A to 5J, various steps of a method for forming an integrated package are illustrated according to an embodiment of the present application. For example, the method may be used to form the integrated package 100 shown in FIG. 1. In the following, the method will be described with reference to FIGS. 5A to 5J in more details.

As shown in FIG. 5A, at least one antenna module 510 is provided, and then is bonded on a carrier 511 via an adhesive layer 513.

In some embodiments, the antenna module 510 may be similar as the antenna module 110 shown in FIG. 1, and may be formed by the method described with reference to FIGS. 4A to 4E. For example, the antenna module 510 may include an antenna module substrate 514 and a top antenna structure 512 disposed on the antenna module substrate 514. Optionally, the antenna module 510 may further include a bottom passivation layer 516 between the antenna module substrate 514 and the top antenna structure 512, and a cap passivation layer 518 covering the top antenna structure 512. The carrier 511 may be, for example, a glass carrier, a metal carrier or any suitable carrier for the manufacturing method of the integrated package. The adhesive layer 513 may include, for example, a preformed double-sided adhesive tape or sheet (e.g., a die-attach tape), a layer of adhesive paste, a layer of liquid adhesive, a printed adhesive, etc.

As shown in FIG. 5B, a first encapsulant 520 is formed on the carrier 511 to encapsulate the antenna module 510. The first encapsulant 520 may include epoxy resin, epoxy resin with filler, epoxy acrylate with filler, or polymer with proper filler, but the scope of this application is not limited thereto. In some embodiments, the first encapsulant 520 may be formed by using compressive molding, transfer molding, liquid encapsulant molding, or other suitable molding processes.

Afterwards, as shown in FIG. 5C, the carrier 511 and the adhesive layer 513 are remove from the first encapsulant 520. In an example, though not shown in FIG. 5C, a second carrier may be coupled to the first encapsulant 520 (e.g., at a side opposite the carrier 511), and then the carrier 511 and the adhesive layer 513 may be removed.

Afterwards, as shown in FIG. 5D, the structure formed in FIG. 5C is flipped and a first redistribution structure 530 is formed on the first encapsulant 520.

In some embodiments, the first redistribution structure 530 can be formed in accordance with a standard Embedded Wafer Level Ball Grid Array (eWLB) process. The first redistribution structure 530 may include one or more dielectric layers and one or more conductive layers between and through the dielectric layers. The conductive layers may define pads, traces and plugs through which electrical signals or voltages can be distributed horizontally and vertically across the first redistribution structure 530. For example, a first dielectric layer 531 may be formed over on the first encapsulant 520, and then a first redistribution layer 532 may be formed in the first dielectric layer 531. A second dielectric layer 533 may be further formed on the first dielectric layer 531, and a second redistribution layer 534 may be formed in the second dielectric layer 533 and electrically connected to the first redistribution layer 532. In the example shown in FIG. 5D, the first redistribution layer 532 may include a first portion 532a serving as a bottom antenna structure, and a second portion 532b serving as an interconnect structure. The bottom antenna structure 532a is connected to the second redistribution layer 534, and is configured for coupling electromagnetic energy with the top antenna structure 512 and transmitting/receiving communication signals to the semiconductor chip formed in subsequent steps.

In some embodiments, an under bump metallization (UBM) structure may be formed on the second redistribution layer 534 and/or on the second dielectric layer 533 (e.g., on portions of the second dielectric layer 533 around a perimeter of openings in the second dielectric layer 533 through which the second redistribution layer 534 is exposed). The UBM structure may include any of a variety of materials (e.g., Ti, Cr, Al, Ti/W, Ti/Ni, Cu, alloys thereof, etc.), and may be formed in any of a variety of manners (e.g., sputtering, electroless plating, chemical vapor deposition (CVD), physical vapor deposition (PVD), atomic layer deposition (ALD), plasma vapor deposition, etc.).

Afterwards, as shown in FIG. 5E, at least one conductive pillar 552 is formed on the first redistribution structure 530. The conductive pillar 552 is electrically connected to the second redistribution layer 534 of the first redistribution structure 530, and used for vertical electrical interconnect.

In some embodiments, the conductive pillar 552 are formed by forming a mask over the first redistribution structure 530, forming openings through the mask to expose the second redistribution layer 534 in locations where the conductive pillar are desired, and depositing a conductive material into the mask openings. In other embodiments, the conductive pillar 552 are formed using other additive, semi-additive, or subtractive metal deposition techniques. The conductive pillars 552 may include any of a variety of conductive materials (e.g., copper, aluminum, silver, gold, nickel, alloys thereof, etc.). For example, the conductive pillars 552 may include copper (e.g., pure copper, copper with some impurities, etc.), a copper alloy, etc.

Afterwards, as shown in FIG. 5F, a semiconductor chip 540 is provided, and then is bonded on the first redistribution structure 530 via an adhesive layer 542. The semiconductor chip 540 may include an integrated circuit chip for wireless communication. In the example shown in FIG. 5F, the semiconductor chip 540 has an active surface 540a and a non-active surface 540b which is opposite to the active surface 540a. A plurality of interconnection bumps (e.g., solder bumps, microbumps, metal pillars, copper balls, etc.) 543 are formed on the active surface 540a of the semiconductor chip 540, and the non-active surface 540b is attached to the adhesive layer 542 with the plurality of interconnection bumps 543 being opposite to the first redistribution structure 530.

Afterwards, as shown in FIG. 5G, a second encapsulant 550 is formed on the first redistribution structure 530 to encapsulate the semiconductor chip 540 (for example, including the interconnection bumps 543) and the conductive pillars 552.

In some embodiments, the second encapsulant 550 may be formed on the first redistribution structure 530 using compressive molding, transfer molding, liquid encapsulant molding, or other suitable molding processes, and may include epoxy resin, epoxy resin with filler, epoxy acrylate with filler, or polymer with proper filler, but the scope of this application is not limited thereto. The second encapsulant 550 may share any or all characteristics with the first encapsulant 520. However, the scope of this application is not limited thereto. For example, the second encapsulant 550 may be formed in a manner different from the manner in which the first encapsulant is formed, and/or the material of the second encapsulant 550 may be different from the material of the first encapsulant 520.

Referring to both FIG. 5G and FIG. 5H, the second encapsulant 550 is grinded to expose the interconnection bumps 543 on the semiconductor chip 540, and the conductive pillars 552.

In some embodiments, an upper portion of the second encapsulant 550 is removed by a grinder 557 shown in FIG. 5H. The grinding process can also planarize the top surface of the second encapsulant 550. After the grinding process, at least respective top surfaces of the interconnection bumps 543 and the conductive pillars 552 are exposed from the top surface of the second encapsulant 550.

Afterwards, referring to FIG. 5I, a second redistribution structure 560 is formed on the second encapsulant 550. The second redistribution structure 560 is electrically coupled with the interconnection bumps 543 and the conductive pillars 552, such that the semiconductor chip 540 can be electrically coupled with the bottom antenna structure 532a in the first redistribution structure 530 via the second redistribution structure 560 and the interconnection bumps 543.

In some embodiments, the second redistribution structure 560 may be formed by using similar steps as that of the first redistribution structure 530. For example, as shown in

FIG. 5I, the second redistribution structure 560 also include two dielectric layers and two conductive layers formed in the two dielectric layers. However, the scope of this application is not limited thereto. For example, the second redistribution structure 560 may be formed in a manner different from the manner in which the first redistribution structure 530 is formed, and/or the materials of the second redistribution structure 560 may be different from the materials of the first redistribution structure 530. In some embodiments, a plurality of contact pads or UBM structures may be formed on the second redistribution structure 560 and electrically coupled with the redistribution layers therein. The UBM structures may include any of a variety of materials (e.g., Ti, Cr, Al, Ti/W, Ti/Ni, Cu, alloys thereof, etc.), and may be formed in any of a variety of manners (e.g., sputtering, electroless plating, CVD, PVD, ALD, plasma vapor deposition, etc.).

At last, referring to FIG. 5J, a plurality of conductive bumps 570 are formed on the second redistribution structure 560 to electrically couple with the second redistribution structure 560.

In some embodiments, an electrically conductive bump material is deposited over the top redistribution layer of the second redistribution structure 560 and/or the UBM structures (if present) which are exposed from the top dielectric layer of the second redistribution structure 560, using one of or any combination of the following processes: evaporation, electrolytic plating, electroless plating, ball drop, or screen printing process. The conductive bump material can be solder, Al, Sn, Ni, Au, Ag, Pb, Bi, Cu, or combinations thereof, with an optional flux solution. For example, the bump material can be eutectic Sn/Pb, high-lead solder, or lead-free solder. The bump material may be reflowed by heating the material above its melting point to form the external interconnection bumps 570. In some embodiments, the conductive bumps 570 may be compression bonded or thermocompression bonded to the second redistribution structure 560. The spherical bumps shown in FIG. 5J may represent one type of external conductive bumps that can be formed on the second redistribution structure 560. In other examples, the conductive bumps 570 may be a stud bump, a micro bump, or other electrical interconnects.

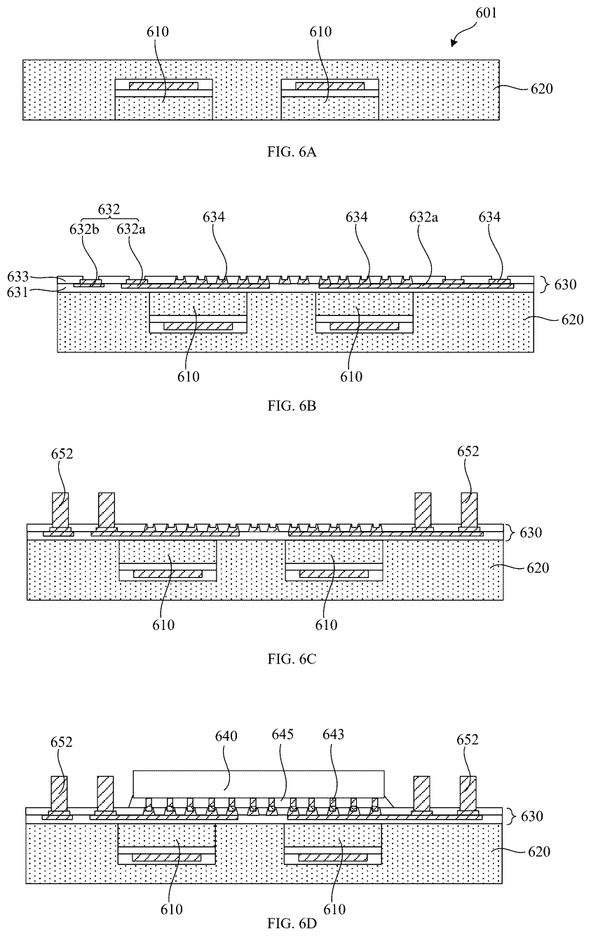

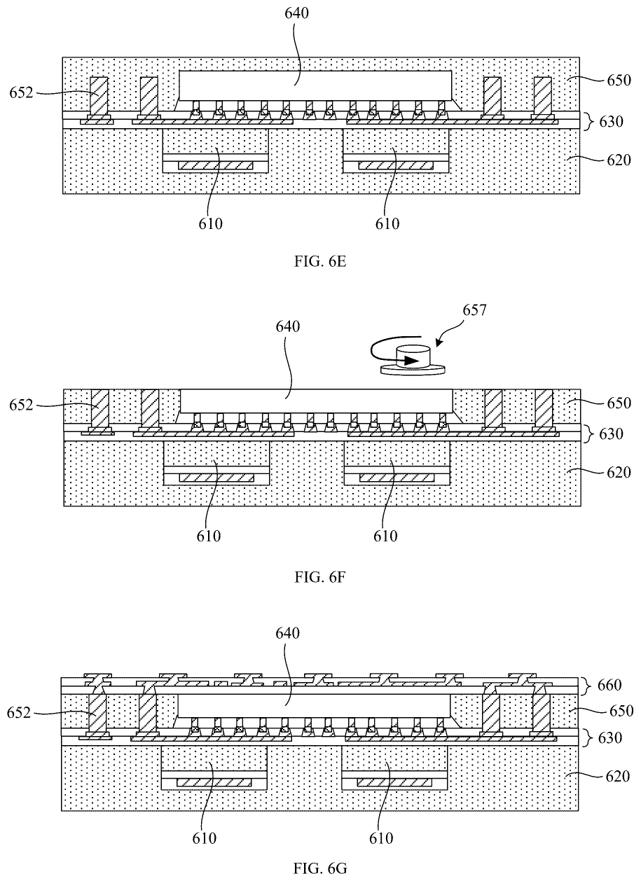

Referring to FIGS. 6A to 6H, cross-sectional views illustrating a method for forming an integrated package are illustrated according to another embodiment of the present application. Different from the embodiment described with reference to FIGS. 5A-5J, the active surface, but not the non-active surface, of the semiconductor chip of this embodiment is bonded to the first redistribution structure.

Referring to FIG. 6A, a package 601 is provided. The package 601 includes at least one antenna module 610, and a first encapsulant 620 encapsulating the antenna module 610. The package 601 shown in FIG. 6A is similar to the structure shown in FIG. 5C, and will not be elaborated herein.

Afterwards, referring to FIG. 6B, the structure formed in FIG. 6A is flipped and a first redistribution structure 630 is formed on the first encapsulant 620.

Specifically, a first dielectric layer 631 may be formed over on the first encapsulant 620, and then a first redistribution layer 632 may be formed in the first dielectric layer 631. A second dielectric layer 633 may be further formed on the first dielectric layer 631, and a second redistribution layer 634 may be formed in the second dielectric layer 633 and electrically connected to the first redistribution layer 632. In the example shown in FIG. 6B, the first redistribution layer 632 may include a first portion 632a serving as a bottom antenna structure, and a second portion 532b serving as an interconnect structure. Different from the example shown in FIG. 5D, the second redistribution layer 634 is also formed in an area above the bottom antenna structure 632a, where the semiconductor chip will be mounted in subsequent steps. A plurality of openings are formed in the second dielectric layer 633 to expose the top surface of the second redistribution layer 634. In some embodiments, UBM structures may be formed in and around the openings in the second dielectric layer 633 through which the second redistribution layer 634 is exposed.

Referring to FIG. 6C, at least one conductive pillar 652 is formed on the first redistribution structure 630. The conductive pillar 652 is electrically connected to the second redistribution layer 634 of the first redistribution structure 630, and used for vertical electrical interconnect.

Referring to FIG. 6D, a semiconductor chip 640 is provided, and then is mounted on the first redistribution structure 630. Interconnection bumps 643 on the active surface of the semiconductor chip 640 are electrically connected to the second redistribution layer 634 of the first redistribution structure 630. For example, solder paste may be deposited or printed onto the exposed second redistribution layer 634 where the semiconductor chip 640 may be mounted. Then, the semiconductor chip 640 may be placed on the top surface of the first redistribution structure 630 with the interconnection bumps 643 in contact with and over the solder paste. The solder paste may be reflowed to mechanically and electrically couple the interconnection bumps 643 to the second redistribution layer 634 of the first redistribution structure 630. In the example shown in FIG. 6D, after the semiconductor chip 640 is mounted on the first redistribution structure 630, a top surface of the semiconductor chip 640 may be higher than a top surface of the conductive pillar 652.

In some embodiments, an underfill encapsulant 645 is further formed between the semiconductor chip 640 and the first redistribution structure 630. The underfill encapsulant 645 may fill in any gaps between the semiconductor chip 640 and the first redistribution structure 630 and optionally cover lateral surfaces of the semiconductor chip 640. The underfill encapsulant 645 may include a polymer composite material, such as epoxy resin, epoxy acrylate, or polymer with or without a filler. For example, the underfill encapsulant 645 is formed by depositing a fluid material at a location on the first redistribution structure 630 that is next to the semiconductor chip 640, and allowing capillary action to draw the fluid material into the space between the semiconductor chip 640 and the first redistribution structure 630. The underfill encapsulant 645 may provide mechanical support to the interconnection between the semiconductor chip 640 and the first redistribution structure 630, helping to mitigate the risk of crack or delamination due to differential thermal expansion between the semiconductor chip 640 and the first redistribution structure 630.

Referring to FIG. 6E, a second encapsulant 650 is formed on the first redistribution structure 630 to encapsulate the semiconductor chip 640 and the conductive pillars 652.

Referring to FIG. 6F, the second encapsulant 650 is grinded to expose the conductive pillars 652, for example, by a grinder 657. The grinding process can remove an upper portion of the second encapsulant 650, and also an upper portion of the semiconductor chip 640. After the grinding process, at least respective top surfaces of the conductive pillars 652 and the semiconductor chip 640 are substantially flush or coplanar with each other.

Referring to FIG. 6G, a second redistribution structure 660 is formed on the second encapsulant 650. The second redistribution structure 660 (e.g., the redistribution layer therein) is electrically coupled with the conductive pillars 652.

At last, as shown in FIG. 6H, a plurality of conductive bumps 670 are formed on the second redistribution structure 660 to electrically couple with the second redistribution structure 660.

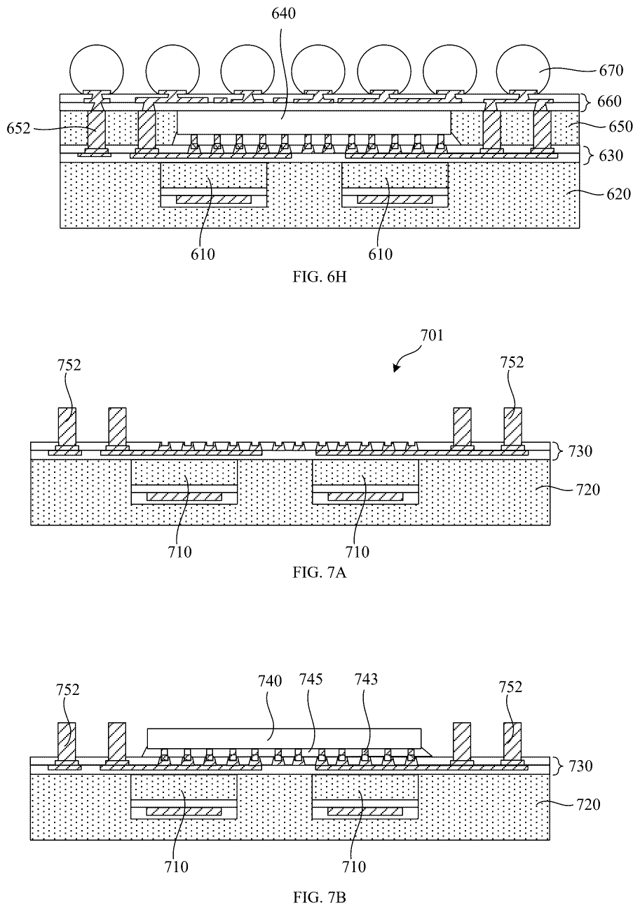

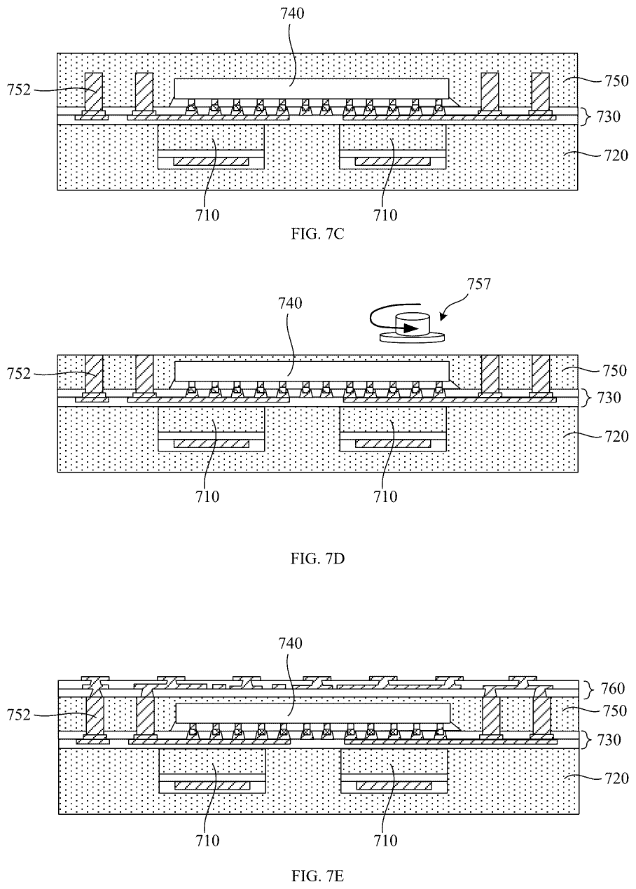

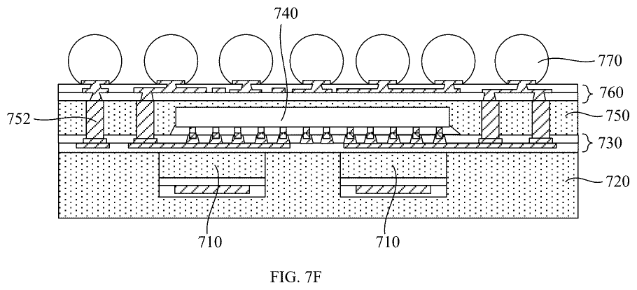

Referring to FIGS. 7A to 7F, cross-sectional views illustrating a method for forming an integrated package are illustrated according to another embodiment of the present application. Different from the embodiment described with reference to FIGS. 6A-6H, a top surface of the semiconductor chip mounted on the first redistribution structure is lower than a top surface of the conductive pillar in this embodiment.

Referring to FIG. 7A, a package 701 is provided. The package 701 includes at least one antenna module 710, and a first encapsulant 720 encapsulating the antenna module 710. A first redistribution structure 730 is formed on the first encapsulant 720, and at least one conductive pillar 752 is formed on the first redistribution structure 730. The package 701 shown in FIG. 7A is similar to the structure shown in FIG. 6C, and will not be elaborated herein.

Referring to FIG. 7B, a semiconductor chip 740 is mounted on the first redistribution structure 730. Interconnection bumps 743 on the active surface of the semiconductor chip 740 are electrically connected to the first redistribution structure 730. In some embodiments, an underfill encapsulant 745 is further formed between the semiconductor chip 740 and the first redistribution structure 730. The underfill encapsulant 745 may fill in any gaps between the semiconductor chip 740 and the first redistribution structure 730 and optionally cover lateral surfaces of the semiconductor chip 740. In the example shown in FIG. 7B, after the semiconductor chip 740 is mounted on the first redistribution structure 730, a top surface of the semiconductor chip 740 may be lower than a top surface of the conductive pillar 752.

Referring to FIG. 7C, a second encapsulant 750 is formed on the first redistribution structure 730 to encapsulate the semiconductor chip 740 and the conductive pillars 752.

Referring to FIG. 7D, the second encapsulant 750 is grinded to expose the conductive pillars 752, for example, by a grinder 757. The grinding process can remove an upper portion of the second encapsulant 750. After the grinding process, the top surface of the conductive pillars 752 is exposed from the second encapsulant 750. As the top surface of the semiconductor chip 740 is lower than the top surface of the conductive pillar 752, there may be a portion of the second encapsulant 750 left above the semiconductor chip 740.

Referring to FIG. 7E, a second redistribution structure 760 is formed on the second encapsulant 750. The second redistribution structure 760 is electrically coupled with the conductive pillars 752.

At last, referring to FIG. 7F, a plurality of conductive bumps 770 are formed on the second redistribution structure 760 to electrically couple with the second redistribution structure 760.

While different processes for forming integrated packages are illustrated in conjunction with FIGS. 5A-5J, FIGS. 6A-6H and FIGS. 7A-7F, it will be appreciated by those skilled in the art that modifications and adaptations to the processes may be made without departing from the scope of the present invention.

For example, although it is only illustrated a single unit of integrated package in the steps of FIGS. 5A-5J, FIGS. 6A-6H and FIGS. 7A-7F, a strip type of integrated packages, i.e., multiple integrated packages formed in a substrate strip, can be made using the processes shown in FIGS. 5A-5J, FIGS. 6A-6H and FIGS. 7A-7F. A singulation step may be further performed to the substrate strip after the step for forming the conductive bumps as shown in FIG. 5J, FIG. 6H and FIG. 7F.

The discussion herein included numerous illustrative figures that showed various portions of an integrated package and a method for making the same. For illustrative clarity, such figures did not show all aspects of each example package. Any of the example packages and/or methods provided herein may share any or all characteristics with any or all other devices and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An integrated package, comprising:
an antenna module comprising:
an antenna module substrate; and
a top antenna structure disposed on the antenna module substrate;
a first encapsulant encapsulating the antenna module;
a first redistribution structure disposed on a bottom surface of the first encapsulant, wherein the first redistribution structure comprises a bottom antenna structure configured for coupling electromagnetic energy with the top antenna structure; and
a semiconductor chip mounted on a bottom surface of the first redistribution structure and electrically coupled with the bottom antenna structure.

2. The integrated package of claim 1, further comprising:
a second encapsulant disposed on the bottom surface of the first redistribution structure and encapsulating the semiconductor chip;
at least one conductive pillar extending through the second encapsulant and electrically coupled with the first redistribution structure; and
a second redistribution structure disposed on a bottom surface of the second encapsulant and electrically coupled with the conductive pillar.

3. The integrated package of claim 2, further comprising:
a plurality of interconnection bumps disposed between the first redistribution structures and the semiconductor chip for electrically coupling the semiconductor chip with the first redistribution structure.

4. The integrated package of claim 3, wherein at least a portion of the second encapsulant is disposed between the semiconductor chip and the second redistribution structure.

5. The integrated package of claim 2, further comprising:
a plurality of interconnection bumps disposed between the second redistribution structures and the semiconductor chip for electrically coupling the semiconductor chip with the second redistribution structure.

6. The integrated package of claim 2, further comprising:
a plurality of conductive bumps disposed on a bottom surface of and electrically coupled with the second redistribution structure.

7. The integrated package of claim 1, wherein the antenna module substrate comprises a molding compound.

8. The integrated package of claim 7, wherein the antenna module further comprises:
a cap passivation layer disposed on the antenna module substrate and covering the top antenna structure.

9. The integrated package of claim 7, wherein the antenna module further comprises:
a bottom passivation layer disposed between the antenna module substrate and the top antenna structure.

10. The integrated package of claim 1, wherein a distance between the top antenna structure and the bottom antenna structure is determined based on patterns of the top antenna structure and the bottom antenna structure, and dielectric constants and dissipation factors of dielectric materials between the top antenna structure and the bottom antenna structure.

11. A method for making an integrated package, comprising:
providing an antenna module, wherein the antenna module comprises an antenna module substrate, and a top antenna structure disposed on the antenna module substrate;
attaching the antenna module on a carrier;
forming a first encapsulant on the carrier to encapsulate the antenna module;
removing the carrier to expose a bottom surface of the first encapsulant;
forming a first redistribution structure on the bottom surface of the first encapsulant, wherein the first redistribution structure comprises a bottom antenna structure configured for coupling electromagnetic energy with the top antenna structure; and
mounting a semiconductor chip on the first redistribution structure, wherein the semiconductor chip is electrically coupled with the bottom antenna structure.

12. The method of claim 11, further comprising:
forming at least one conductive pillar on the first redistribution structure;
forming a second encapsulant on the first redistribution structure to encapsulate the semiconductor chip; and
forming a second redistribution structure on the second encapsulant, wherein the second redistribution structure is electrically coupled with the first redistribution structure via the conductive pillar.

13. The method of claim 12, wherein mounting the semiconductor chip on the first redistribution structure comprises:
forming a plurality of interconnection bumps on an active surface of the semiconductor chip; and
mounting the semiconductor chip on the first redistribution structure via the plurality of interconnection bumps.

14. The method of claim 13, wherein at least a portion of the second encapsulant is formed between the semiconductor chip and the second redistribution structure.

15. The method of claim 12, wherein mounting the semiconductor chip on the first redistribution structure comprises:
forming a plurality of interconnection bumps on an active surface of the semiconductor chip; and
attaching the semiconductor chip on the first redistribution structure with the plurality of interconnection bumps being opposite to the first redistribution structure.

16. The method of claim 12, further comprising:
forming a plurality of conductive bumps on the second redistribution structure to electrically couple with the second redistribution structure.

17. The method of claim 12, wherein providing the antenna module comprises:
providing a molded substrate comprising a molding compound; and
forming the top antenna structure on the molded substrate.

18. The method of claim 17, wherein providing the antenna module further comprises:
forming a bottom passivation layer on the molded substrate, before forming the top antenna structure on the molded substrate.

19. The method of claim 17, wherein providing the antenna module further comprises:
forming a cap passivation layer on the top antenna structure.
